(19) United States
(12) Patent Application Publication
(10) Pub. No.: US 2009/0289352 A1
(43) Pub. Date: Nov. 26, 2009

(54) SEMICONDUCTOR DEVICE AND A METHOD FOR MANUFACTURING THE SEMICONDUCTOR DEVICE

(75) Inventor: Masanao HORIE, Kanagawa (JP)

Correspondence Address: YOUNG & THOMPSON, 209 Madison Street, Suite 500, ALEXANDRIA, VA, 22314, US

(73) Assignee: NEC ELECTRONICS CORPORATION, KANAGAWA (JP)

(21) Appl. No.: 12/470,703

(22) Filed: May 22, 2009

(30) Foreign Application Priority Data
May 26, 2008 (JP) 2008-136575

(51) Int. Cl. H01L 23/34; H01L 21/50

(52) U.S. Cl. 257/712; 438/122; 257/E21.499; 257/E23.08

(57) ABSTRACT

A semiconductor device includes: a first substrate, having a grounding layer and holes formed therein for filling with an electroconductive material; a semiconductor chip over such first substrate; and an electroconductive heat releasing member, electrically coupled to the semiconductor chip able to release heat from the semiconductor chip. The heat releasing member includes a ceiling section covering the surface of the semiconductor chip and side surface extending from the ceiling section toward the sides of the first substrate. The ceiling section of the heat releasing member and the side surface sections are formed to compose an integral member. Tips of the side surface sections are inserted in the respective holes of the first substrate. The tips of the side surface section, in turn, are fixed in the inside of the respective holes with the electroconductive material, and the tips are electrically coupled to the grounding layer through the electroconductive material.

This application is based on Japanese patent application No. 2008-136,575, the content of which is incorporated hereinto by reference.

### BACKGROUND

1. Technical Field

The present invention relates to a semiconductor device and a method for manufacturing a semiconductor device.

2. Related Art

Conventionally, a manner for installing a circuit board having a semiconductor chip installed on a motherboard of a printed board and the like is adopted. For example, a circuit board is mounted on a printed circuit board through a ball grid array or the like, and a semiconductor chip is installed on such circuit board through the ball grid array. In such semiconductor device, a surface (semiconductor substrate) of the semiconductor chip in the side opposite to the circuit board is required to be grounded to the printed board.

For example, Japanese Patent Laid-Open No. 2003-100,924 discloses a semiconductor device 700 shown in FIG. 7. The semiconductor device 700 includes an insulating substrate 702 installed on an external electric circuit device 70 and a semiconductor element 703 installed on the insulating substrate 702. An interconnect conductor 702A extending from an upper surface to a lower surface of the insulating substrate 702 is formed in the insulating substrate 702. The semiconductor element 703 is coupled with the external electric circuit device 701 through solders 705, an interconnect conductor 702A, metal balls 706 and the like.

Japanese Patent Laid-Open No. 2004-247,589 discloses a semiconductor device 800 shown in FIG. 8. Such semiconductor device 800 includes a substrate 801 and a semiconductor package 802 installed on the substrate 801. The semiconductor package 802 includes semiconductor element 802A in the inside thereof, and the semiconductor element 802A is grounded to the substrate 801 through terminals 803, a heat sink 804 and a fixing member 805, which are provided on the upper surface of the semiconductor package 802. The fixing member 805 functions as fixing the heat sink 804 on the semiconductor package 802, and the end thereof extends through the substrate 801, and is curved toward the side of the back surface of the substrate 801. A tip of the fixing member 805 is in contact with the terminals of the back surface of the substrate 801 to press against the substrate 801 and the terminal 801A.

Japanese Patent Laid-Open No. 2003-68,899 discloses a semiconductor device 900 shown in FIG. 9. Such semiconductor device 900 includes a large scale integrated circuit (LSI) package 901 including a semiconductor chip 901B installed on a carrier 901A, and a printed board 902 having such LSI package 901 installed thereon. The LSI package 901 includes a heat spreader 901C which thermally bonded with the semiconductor chip 901B. The heat spreader 901C is coupled to a heat dissipation shielding unit 903, and the heat dissipation shielding unit 903 is coupled to a coupling unit 904. The coupling unit 904 is inserted in the printed board 902 to be coupled to a grounding layer 902A of the printed board 902.

There are the following problems in the semiconductor devices having the above-described configurations.

Since the semiconductor element 703 is coupled with the external electric circuit device 701 through solders 705, an interconnect conductor 702A, metal balls 706 and the like in the semiconductor device 700 described in Japanese Patent Laid-Open No. 2003-100,924, the coupling resistance and the inductance of the sections starting from the semiconductor element 703 to the external electric circuit device 701 are increased. Thus, even in the case where the semiconductor element 703 is coupled to the external electric circuit device 701 to be grounded, a potential difference is caused between the semiconductor element 703 and the external electric circuit device 701, failing to ensure grounding the semiconductor element 703.

Since the tip of the fixing member 805 is coupled to the terminal 801A by pressing the terminal 801A in the back surface of the substrate 801 with the tip of the fixing member 805 in the semiconductor device 800 of Japanese Patent Laid-Open No. 2004-247,589, the coupling resistance may possibly be increased. Therefore, it becomes difficult to ensure the semiconductor element to be grounded.

Since the heat dissipation shielding unit 903 or the coupling unit 904 is required to be grounded to the ground plane of the carrier 901A in the technology described in Japanese Patent Laid-Open No. 2003-68,899, complicated configurations are required for the heat dissipation shielding unit 903 or the coupling unit 904. Since, for example, pawls are formed in the heat dissipation shielding unit 903 to provide contacts with the front and the back surfaces of the carrier 901A, a complicate configuration is required for the heat dissipation shielding unit 903. Therefore, it is difficult to form the heat spreader 901C, the heat dissipation shielding unit 903 and the coupling unit 904 as a single integral member in the technology described in Japanese Patent Laid-Open No. 2003-68,899. Therefore, larger coupling resistance may have been possibly generated when the semiconductor chip 901B is grounded to the grounding layer 902A of the printed board 902 through the heat spreader 901C, the heat dissipation shielding unit 903 and the coupling unit 904. Further, since the coupling unit 904 of Japanese Patent Laid-Open No. 2003-68,899 is simply configured by the manner, in which a strip-like metal band is vertically curved, and the curved metal band is inserted in a hole of the printed board 902 to be in contact with the grounding layer 902A exposed over the inside of the hole, it is difficult to ensure the contact between the coupling unit 904 and the grounding layer 902A.

### SUMMARY

According to one aspect of the present invention, there is provided a semiconductor device, comprising: a first substrate, having a grounding layer and a hole formed therein; a semiconductor chip disposed over the first substrate; and an electroconductive heat releasing member, electrically coupled to the semiconductor chip and releasing heat from the semiconductor chip, wherein the heat releasing member comprises a ceiling section covering the surface of the semiconductor chip and a side surface section extending from the ceiling section toward the side of the first substrate, and the ceiling section and the side surface section are formed to compose an integral member, and wherein a tip of the side surface section is inserted in the hole of the first substrate, and is fixed in the inside of the hole by an electroconductive material buried in the inside of the hole, and is electrically coupled to the grounding layer at the side wall of the hole via the electroconductive material.

According to the above-described aspect of the present invention, the heat releasing member is electrically coupled with the semiconductor chip, and the tip of the side surface section is coupled with the grounding layer of the first substrate. Therefore, it is configured that the semiconductor chip is grounded to the first substrate through the heat releasing member. Here, since the heat releasing member has the ceiling section covering the surface of the semiconductor chip and the side surface section, which are formed to compose an integral member, a generation of a larger coupling resistance between the semiconductor chip and the grounding layer of the first substrate can be prevented. This allows ensuring a grounding of the semiconductor chip. Further, the tip of the side surface section of the heat releasing member is inserted in the hole of the first substrate, and is fixed in the inside of the hole by an electroconductive material, and the tip of the side surface section is electrically coupled with the grounding layer through the electroconductive material filling the hole. This allows ensuring the contact between the tip of the side surface section of the heat releasing member and the grounding layer, thereby ensuring the grounding of the semiconductor chip.

According to another aspect of the present invention, a method for manufacturing the semiconductor device as described above can be provided. More specifically, according to another aspect of the present invention, there is provided a method for manufacturing a semiconductor device, including: preparing a first substrate having a grounding layer and a hole formed therein; installing a semiconductor chip over the first substrate; and fixing an electroconductive heat releasing member over the first substrate, the electroconductive heat releasing member being electrically coupled to the semiconductor chip and releasing heat from the semiconductor chip; wherein the heat releasing member comprises a ceiling section covering the semiconductor chip and a side surface section extending from the ceiling section toward the side of the first substrate, and the ceiling section and the side surface section are formed to compose an integral member, and wherein, in the fixing the heat releasing member, a tip of the side surface section of the heat releasing member is inserted in the hole of the first substrate, and the tip of the side surface section is electrically coupled to the grounding layer through the electroconductive material by filling the inside of the hole with electroconductive material, and the tip of the side surface section is fixed in the inside of the hole by the electroconductive material.

According to the present invention, the semiconductor device, which ensures the grounding of the semiconductor chip, and the method for manufacturing such semiconductor device, are provided.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a cross-sectional view, illustrating a semiconductor device according to first embodiment of the present invention;

FIG. 2 is an exploded perspective view of a semiconductor device;

FIGS. 3A and 3B are cross-sectional views, illustrating a process for manufacturing a semiconductor device;

FIGS. 4A and 4B are cross-sectional views, illustrating a process for manufacturing a semiconductor device;

FIG. 5 is a cross-sectional view, illustrating manufacturing process of semiconductor device.

FIG. 6 is a cross-sectional view, illustrating the process for manufacturing a semiconductor device;

FIG. 7 is a schematic diagram, illustrating a conventional semiconductor device;

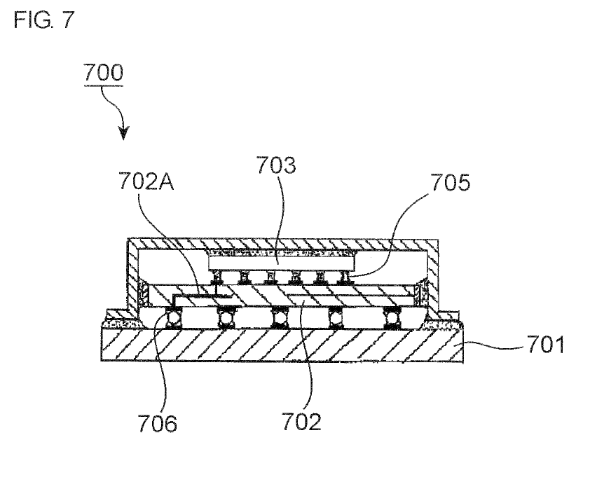

FIG. 8 is a schematic diagram, illustrating a conventional semiconductor device; and

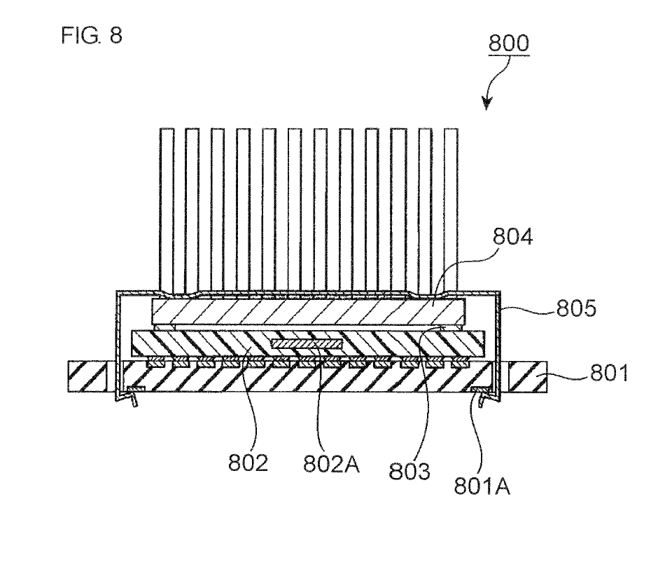

FIG. 9 is a schematic diagram, illustrating a conventional semiconductor device.

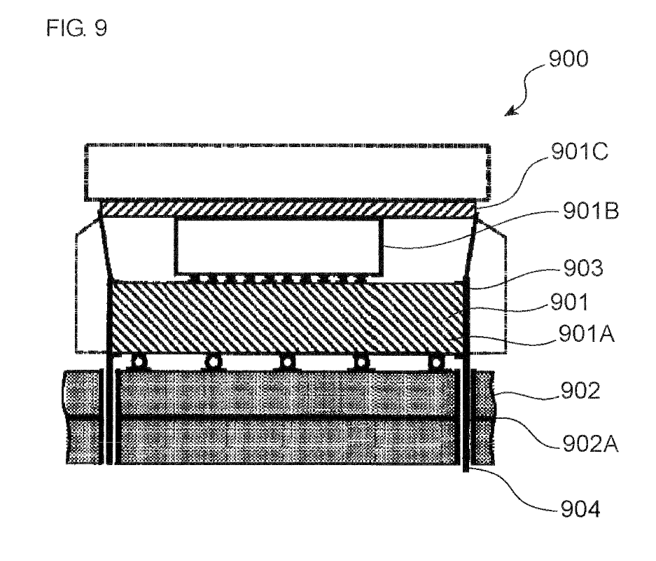

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposed.

Exemplary implementations according to the present invention will be described in detail as follows in reference to the annexed figures. In all figures, an identical numeral is assigned to an element commonly appeared in the figures, and the detailed description thereof will not be repeated.

### First Embodiment

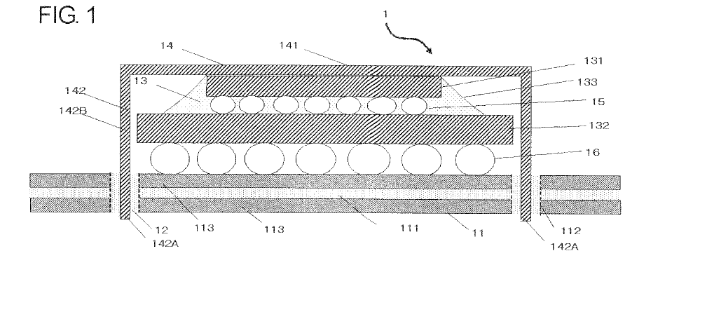

In the beginning, a semiconductor device 1 of the present embodiment will be described, in reference to FIG. 1. The semiconductor device 1 of the present embodiment includes: a first substrate 11, having a grounding layer 111, and also having holes 112 formed therein for being filled with an electroconductive material 12; a semiconductor chip 131 disposed over such first substrate; and an electroconductive heat releasing member 14, electrically coupled to the semiconductor chip 131 and capable of releasing heat from the semiconductor chip 131. The heat releasing member 14 includes a ceiling section 141 covering the surface of the semiconductor chip 131 and side surface sections 142 extending from the ceiling section 141 toward the sides of the first substrate 11. The ceiling section 141 of the heat releasing member 14 and the side surface sections 142 are formed to compose an integral member. Tips 142A of the side surface sections 142 are inserted in the respective holes 112 of the first substrate 11.

The tips 142A of the side surface section 142, in turns are fixed in the inside of the respective holes 112 with the electroconductive material 12, and the tips 142A are electrically coupled to the grounding layer 111 at the side walls of the holes 112 through the electroconductive material 12.

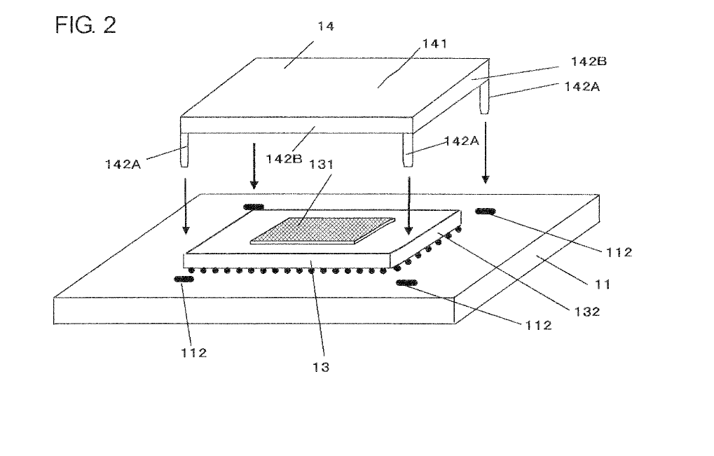

Next, the details of the semiconductor device 1 will be described. The first substrate 11 serves as a main substrate for installing the semiconductor package 13 including the semiconductor chip 131. Such first substrate 11 is configured to include, though it is not shown, a plurality of interconnect layers and a plurality of insulating layers, which are alternately disposed, and the grounding layer 111 is disposed within such layers. More specifically, the grounding layer 111 is configured to be disposed between a pair of substrate body sections 113, which include the interconnect layers and the insulating layers provided between the interconnect layers. The grounding layer 111 is, for example, a metallic layer such as a copper foil layer and the like. Such first substrate 11 is provided with holes 112 formed therein to extend from the front surface to the back surface (through hole). A portion of the side wall of the hole 112 is composed of the grounding layer 111. Further, the inside of the hole 112 is filled with an electroconductive material 12. The holes 112 are formed in regions adjacent to a region for installing the semiconductor package 13 of the first substrate 11. In the present embodiment, as shown in FIG. 2, such regions are formed in multiple regions (four regions), each of which is adjacent to the corresponding corner of the region for installing the semiconductor package 13.

The semiconductor package 13 is installed on the first substrate 11, and includes the semiconductor chip 131 and a second substrate 132, on which this semiconductor chip 131 is installed. The semiconductor chip 131 is an LSI chip, and is installed on the second substrate 132 through solder bumps (ball grid arrays) 15 provided on the surface of the semiconductor chip 131. The semiconductor chip 131 is installed in a flip-chip configuration over the second substrate 132, and, in turn, the semiconductor chip 131 is electrically coupled to the second substrate 132 through the solder bumps 15. The peripheral portions of the solder bump 15 are filled with an under fill resin 133 to provide a protection for the solder bumps 15.

Solder bumps 16 (BGA ball) are provided on another surface of the second substrate 132 opposite to the semiconductor chip 131. The second substrate 132 is also installed in a flip-chip configuration over the first substrate 11, and, in turn, and the semiconductor package 13 is electrically coupled to the first substrate 11 through the solder bumps 16.

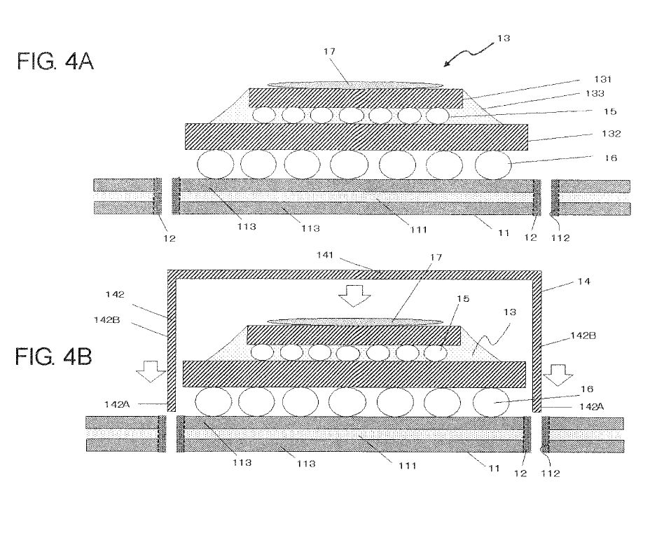

The heat releasing member 14 serves as releasing heat generated in the semiconductor chip 131 of the semiconductor package 13, and is so-called heat spreader. Such heat releasing member 14 includes the ceiling section 141 covering the semiconductor chip 131 and the side surface section 142 extends downwardly (shown as downwardly in the drawing for the illustrating purpose) from the ceiling section 141 toward the side of the first substrate 11. The ceiling section 141 is a flat plate-like shaped, and has a rectangular geometry in a viewpoint from the side of the front surface of the first substrate 11. The ceiling section 141 is coupled to the surface of the semiconductor chip 131 through an electrically conducting paste 17 (see FIGS. 4A and 4B). The ceiling section 141 has sufficient dimension for completely covering the surface of the semiconductor chip 131 and the dimension is larger than the surface of the semiconductor chip 131. The side surface section 142 includes, as shown in FIG. 1 and FIG. 2, main frames 142B of the side surface section having flat plate shape, each of which extends downwardly from each side of the ceiling section 141 toward the side of the first substrate 11, and the tips 142A provided at each end of the main frames 142B of the side surface section. The main frames 142B of the side surface section and the ceiling section 141 form a box form of a rectangular solid shape having an open in the bottom surface.

When the heat releasing member 14 is fixed to the first substrate 11, peripheral sections of the semiconductor package 13 and the solder humps 16 are completely coated with a plurality of main frames 142B of the side surface section. This allows providing a shield from electromagnetic wave generated by the semiconductor package 13 with the heat releasing member 14.

The tip 142A are protruded members provided in the end sections of the main frames 142B of the side surface section in the side of the first substrate 11, and protrude toward the side of the first substrate 11, and are formed to be strip-shaped and flat plate-shaped. The dimensional width of the tip 142A (the dimension in the direction along the surface of the first substrate 11) is narrower than the dimensional width of the main frame 142B of the side surface section (dimension in the direction along the surface of the first substrate 11), and the tip 142A has the dimensional width, which is conformable for being inserted in the hole 112. The tip 142A is inserted in the hole 112 and is fixed by the electroconductive material 12 that is filled in the hole 112. Further, the tip is electrically coupled with the grounding layer 111 of the inner surface of the hole 112 through the electroconductive material 12. This allows the semiconductor chip 131 being electrically coupled to, and is grounded with, the grounding layer 111 through the heat releasing member 14. In such case, the tip 142A may be protruded from the aperture of the hole 112, or may not be protruded from the aperture of the hole 112, when the tip 142A is inserted in the hole 112. Further, an electrical conduction paste 12 such as solder, silver and the like may be employed for the electroconductive material 12.

The heat releasing member 14 as described above is composed of a member having sufficient electroconductivity and better heat releaseability. For example, a material of a copper sheet or the like may be employed for the heat releasing member 14. Further, the heat releasing member 14 is configured of the ceiling section 141, the main frame 142B of the side surface section and the tips 142A, all of which are formed to compose an integral member. More specifically, the heat releasing member 14 may be molded by a press molding process.

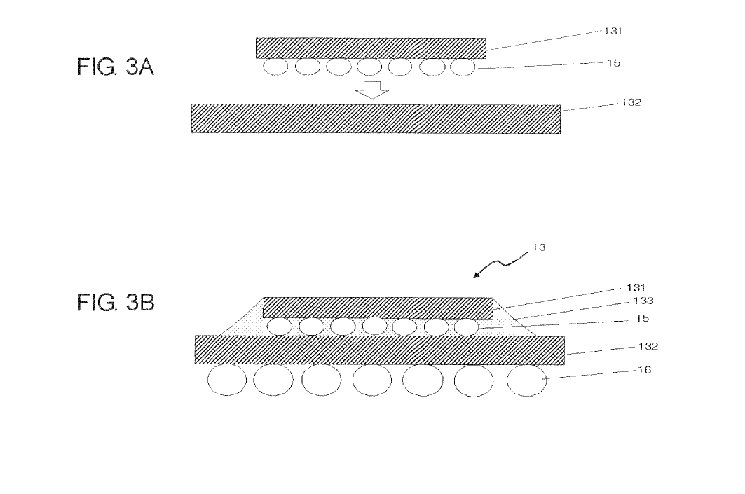

Next, the process for manufacturing the semiconductor device 1 will be described in reference to FIGS. 3A and 3B, FIGS. 4A and 4B and FIG. 5. First of all, a general outline of the process for manufacturing the semiconductor device 1 will be described. The process for manufacturing the semiconductor device 1 of the present embodiment includes: preparing the first substrate 11 having the grounding layer 111 and the hole 112 formed therein and filled with the electroconductive material 12; installing the semiconductor chip 131 on the first substrate 11; and fixing, on the first substrate 11, the electroconductive heat releasing member 14, which is electrically coupled to the semiconductor chip 131 and releases heat from the semiconductor chip 131. In the operation for fixing the heat releasing member 14 on the first substrate 11, the tip 142A of the side surface section 142 of the heat releasing member 14 is inserted in the hole 112 of the first substrate 11, and the tip 142A of the side surface section 142 is electrically coupled to the grounding layer 111 through the electroconductive material 12, and the tip 142A of the side surface section 142 is fixed in the inside of the hole 112 by the electroconductive material 12.

Next, the process for manufacturing the semiconductor device 1 of the present embodiment will be described in detail. First of all, as shown in FIG. 3A, the solder bumps 15 are provided on the semiconductor chip 131. More specifically, the solder bumps are formed on the electrode pad formed on the surface of the semiconductor chip 131 (not shown), and then a reflow process is carried out to form the solder bumps 15. The solder bumps 15 may alternatively be formed by installing micro balls on the electrode pad (not shown), or may be formed by screen-printing the soldering paste. Next, the semiconductor chip 131 is installed on the second substrate 132. A flux (not presented) is applied over the electrode pad (not shown) of the second substrate 132. Then, the solder bumps 15 are installed on the electrode pad, and a reflow process is carried out at a temperature of about 250 degrees C., so that the solder bumps 15 are melted to physically and electrically couple the semiconductor chip 131 with the second substrate 132. Subsequently, as shown in FIG. 3B, an under fill resin 133 is provided as a protective material for the solder bumps 15. It is common that the injection of the under fill resin 133 is conducted from the periphery of the semiconductor chip 131 by employing a dispenser, and after a certain time is passed, a baking process is carried out at a temperature of about 150 degrees C. for about 2 hours. This procedure provides a completion of the semiconductor package 13. Subsequently, the solder bumps 16 are provided on the surface of the second substrate 132 opposite to the side of the semiconductor chip 131. A flux (not presented) is applied over the electrode pad (not presented) on the surface of the second substrate 132 opposite to the side of the semiconductor chip 131, and the solder bumps 16 are disposed on the respective electrode pads, and then a reflow process is carried out at a temperature of about 250 degrees C.

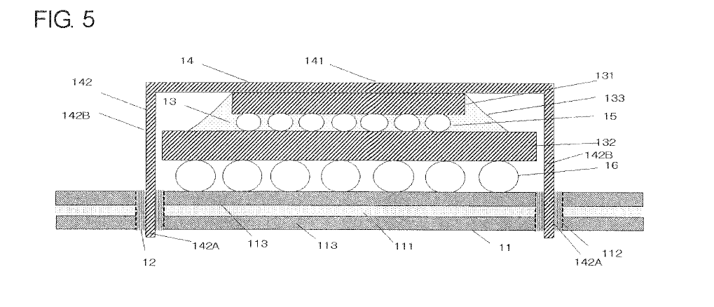

Next, as show in FIG. 4A, for the semiconductor package 13, an electrically conducting paste 17 is applied over the surface (surface opposite to the second substrate 132) of the semiconductor chip 131, and the inside of the hole 112 of the first substrate 11 is filled with the electrically conducting paste 12. The material for the electrically conducting paste 17 is the same as that for that electrically conducting paste 12. In this occasion, the inside of the hole 112 is filled with the electrically conducting paste 12 by employing a dispenser. Next, a flux is applied over the electrode pads (not shown) on the surface of the first substrate 11, and the semiconductor package 13 is installed on the first substrate 11. More specifically, the solder bumps 16 are installed on the electrode pads. Next, as shown in FIG. 4B, the tips 142A of the heat releasing member 14 are inserted in the holes 112, and the ceiling section 141 of the heat releasing member 14 is installed on the surface of the semiconductor chip 131, and then the ceiling section 141 of the top of the heat releasing member 14 is lightly pressed. Subsequently, a reflow process is carried out for the semiconductor device 1 at a temperature of about 250 degrees C. to physically and electrically couple the second substrate 132 with the first substrate 11, and the heat releasing member 14 is fixed to the first substrate 11 and the semiconductor chip 131 (FIG. 5).

In such case, a heat-resistant paste is preferably employed for the electrically conducting pastes 12 and 17. While fixing the heat releasing member 14 to the first substrate 11 and the semiconductor chip 131 is conducted simultaneously with fixing the second substrate 132 to the first substrate 11 in the present embodiment, the operation for the fixing is not limited thereto, and the operation for fixing the heat releasing member 14 to the first substrate 11 and the semiconductor chip 131 is separately carried out from the operation for fixing the second substrate 132 to the first substrate 11. For example, the second substrate 132 may be installed on the first substrate 11, and a reflow may be conducted to fix thereof, and then the heat releasing member 14 may be installed on the first substrate 11, and then another reflow may be conducted.

Next, advantageous effects of the present embodiment will be described. The heat releasing member 14 is electrically coupled to the semiconductor chip 131, and the tip 142A of the side surface section 142 is coupled to the grounding layer 111 of the first substrate 11. Therefore, the semiconductor chip 131 is grounded to the first substrate 11 through the heat releasing member 14. Since the ceiling section 141 for covering the surface of the semiconductor chip 131 and the side surface sections 142 are formed to be an integral member in the heat releasing member 14, larger coupling resistance between the semiconductor chip 131 and the grounding layer 111 of the first substrate 11 can be prevented. This ensures the grounding of the semiconductor chip 131. In particular, the heat releasing member 14 of the present embodiment is configured to include the flat ceiling section 141, the flat main frame 142B of the side surface section extending downwardly from each arm of the ceiling section 141, and the strip-shaped tips 142A coupled with the main frame 142B of the side surface section, and thus the shape of the heat releasing member 14 is relatively simple, so that the heat releasing member 14 can be integrally formed in a simple process.

Further, the tips 142A of the heat releasing member 14 are inserted in the holes 112 of the first substrate 11, and the tips 142A are fixed in the holes 112 by the electroconductive material 12 filling the holes 112. Further, the tips 142A are electrically coupled with the grounding layer 111 through the electroconductive material 12 filling the holes 112. This ensures the tips 142A of the heat releasing member 14 being in contact with the grounding layer 111, and, in turn, grounding the semiconductor chip 131.

In the conventional semiconductor device 900 disclosed in Japanese Patent Laid-Open No. 2003-68,899, the coupling unit 904 is simply configured by the manner, in which a strip-like metal band is vertically curved, and the curved metal band is inserted in a hole of the printed board 902 to be in contact with the grounding layer 902A exposed over the inside of the hole. Therefore, insufficient contact of the coupling unit 904 with the grounding layer 902A may be caused due to an inappropriate dimension of the coupling unit 904 or a misalignment of the coupling unit 904 over the hole and the like, leading to a difficulty in obtaining the grounding. On the contrary, in the present embodiment, the hole 112 is filled with the electroconductive material 12, and the grounding layer 111 is electrically coupled to the tips 142A of the heat releasing member 14 through the electroconductive material 12 to ensure the grounding to the semiconductor chip 131.

Further, in the present embodiment, the tip 142A of the side surface section 142 of the heat releasing member 14 may have a sufficient length dimension for electrically coupling with the grounding layer 111 in the hole 112. Therefore, higher accuracy in processing the tip 142A of the side surface section 142 is not required, and thus higher processing accuracy is not required for forming the heat releasing member 14. Further, since it is required to press the terminal 801A in the back surface of the substrate with the tip of the fixing member 805 in the fixing member 805 disclosed in Japanese Patent Laid-Open No. 2004-247,589, the tip is curved. Therefore, it is necessary to form a larger hole of the substrate 801, through which the tip of the fixing member 805 is extended. On the contrary, in the present embodiment, the tip 142A is formed as being strip-like shaped. Since the end section of the tip 142A is not curved, it is not necessary to have larger dimension of the hole 112, through which the tip 142A is extended. This prevents a limitation for the guidance of the wires or the like in the first substrate 11 due to the presence of the hole 112.

Further, since the dispenser is employed when the electrically conducting paste 12 is injected in hole 112 in the present embodiment, the desired quantity of the electrically conducting paste 12 can be injected.

Further, in the present embodiment, the electrically conducting paste 12 is supplied in the hole 112 of the first substrate 11, and the tips 142A of the heat releasing member 14 are inserted in the holes 112, and after the second substrate 132 is mounted on the first substrate 11, the reflow of the semiconductor device is conducted. This allows achieving the fixing of the heat releasing member 14 to the first substrate 11, simultaneously with achieving the fixing of the second substrate 132 to the first substrate 11. The reflow for fixing the heat releasing member 14 to the first substrate 11 is conducted simultaneously with the reflow for fixing the second substrate 132 to the first substrate 11, so that the thermal history for the semiconductor chip 131 can be reduced.

### Second Embodiment

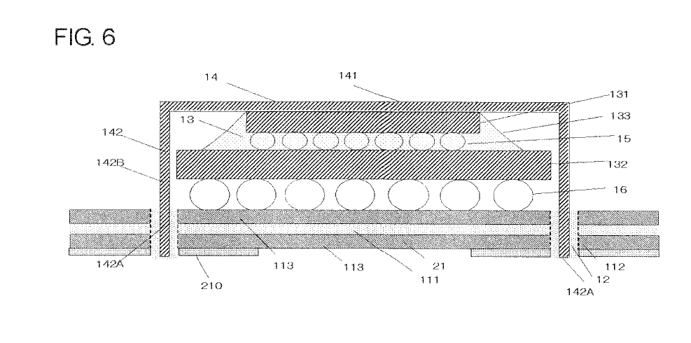

Second embodiment of the present invention will be described in reference to FIG. 6. In the present embodiment, the first substrate 21 has a grounding interconnect 210 in a surface thereof opposite to the surface in the side having the semiconductor chip 131. The grounding interconnect 210 is coupled to a feeding connector (not shown), which is provided for providing a grounding electric potential for the grounding interconnect 210. Other configurations of the first substrate 21 are similar to the first substrate 11. The tips 142A of the heat releasing member 14 are protruded from the apertures of the holes 112, and the tip 142A of the side surface section 142 is coupled to the grounding interconnect 210 through the electroconductive material 12 supplied in the holes 112. Other configurations are similar to the previous embodiment.

According to the present embodiment described above, the following advantageous effects can be obtained, in addition to enjoying the same advantageous effects as obtainable in first embodiment. The tips 142A of the heat releasing member 14 are coupled to grounding interconnect 210. The grounding interconnect 210 is coupled to the feeding connector for providing a grounding electric potential. Therefore, a grounding electric potential is provided to the semiconductor chip 131 from the feeding connector through the grounding interconnect 210 and the heat releasing member 14. Therefore, further stabilization of the grounding electric potential can be achieved.

The present invention is not limited to the above-described embodiments, and modifications, improvements and the like within the range for achieving the object of the present invention are included in the present invention. For example, while the semiconductor package 13 is mounted on the first substrate 11 in the aforementioned embodiment, the configuration of the present invention is not limited thereto, and the semiconductor chip 131 may alternatively be directly mounted on the first substrate 11. Further, while the tips 142A of the heat releasing member 14 are strip-shaped protruded from the main frame 142B of the side surface section of the heat releasing member 14 in the aforementioned embodiment, the feature of the tip 142A is not one limited thereto.

It is apparent that the present invention is not limited to the above embodiment, and may be modified and changed without departing from the scope and spirit of the invention.

What is claimed is:

1. A semiconductor device, comprising:
a first substrate, having a grounding layer and a hole formed therein;
a semiconductor chip disposed over said first substrate; and
an electroconductive heat releasing member, electrically coupled to said semiconductor chip and releasing heat from said semiconductor chip,
wherein said heat releasing member comprises a ceiling section covering the surface of said semiconductor chip and a side surface section extending from said ceiling section toward the side of said first substrate, and said ceiling section and said side surface section are formed to compose an integral member, and
wherein a tip of said side surface section is inserted in said hole of said first substrate, and is fixed in the inside of said hole by an electroconductive material buried in the inside of said hole, and is electrically coupled to said grounding layer at the side wall of said hole via said electroconductive material.

2. The semiconductor device as set forth in claim 1,
wherein said semiconductor chip is installed on a second substrate through a bump, wherein a semiconductor package is configured to have said semiconductor chip and said second substrate, and
wherein said second substrate is installed over the said first substrate.

3. The semiconductor device as set forth in claim 1,
wherein said electrocondutive material is an electrically conducting paste.

4. The semiconductor device as set forth in claim 3, wherein said electrically conducting paste is solder.

5. The semiconductor device as set forth in claim 1,
wherein a tip of said side surface section of said heat releasing member is presented to be strip-shaped,
wherein said first substrate includes a grounding interconnect in a surface thereof opposite to the surface in the side of said semiconductor chip;
wherein said hole is a through hole extending through said first substrate; and
wherein the tip of said side surface section is coupled with said grounding interconnect through said electroconductive material disposed up in said hole.

6. A method for manufacturing a semiconductor device, including:
preparing a first substrate having a grounding layer and a hole formed therein;
installing a semiconductor chip over said first substrate; and
fixing an electroconductive heat releasing member over said first substrate, said electroconductive heat releasing member being electrically coupled to said semiconductor chip and releasing heat from said semiconductor chip;
wherein said heat releasing member comprises a ceiling section covering said semiconductor chip and a side surface section extending from said ceiling section toward the side of said first substrate, and said ceiling section and said side surface section are formed to compose an integral member, and
wherein, in said fixing said heat releasing member, a tip of the side surface section of said heat releasing member is inserted in said hole of said first substrate, and the tip of said side surface section is electrically coupled to said grounding layer through said electroconductive material by filling the inside of said hole with electroconductive material, and the tip of said side surface section is fixed in the inside of the hole by the electroconductive material.

7. The method for manufacturing the semiconductor device as set forth in claim 6, wherein said fixing the heat releasing member includes said electroconductive material is injected into said hole formed in said first substrate by employing a dispenser.

8. The method for manufacturing the semiconductor device as set forth in claim 6,
wherein said semiconductor chip is installed over a second substrate,
wherein said installing the semiconductor chip over said first substrate includes installing said second substrate over said first substrate through a solder bump, said second substrate having said semiconductor chip installed thereon, and
wherein, in said fixing the electroconductive heat releasing member, a reflow is carried out for the semiconductor device after the tip of side surface section of said heat releasing member is inserted into said hole of said first substrate and the inside of said hole is filled with said electroconductive material, so that the tip of said side surface section is fixed into the inside of the hole with said electroconductive material and so that said second substrate is fixed to said first substrate with said solder bump.
